(19) United States
(12) Patent Application Publication
(10) Pub. No.: US 2025/0053086 A1
(43) Pub. Date: Feb. 13, 2025

(54) POST DEVELOPMENT TREATMENT FOR METAL-OXIDE PHOTORESISTS

(71) Applicant: Applied Materials, Inc., Santa Clara, CA (US)

(72) Inventors: MADHUR SACHAN, Belmont, CA (US); BO XIE, San Jose, CA (US); LAKMAL CHARIDU KALUTARAGE, San Jose, CA (US); ZHENXING HAN, Sunnyvale, CA (US); TZU SHUN YANG, Milpitas, CA (US); LI-QUN XIA, Cupertino, CA (US)

(21) Appl. No.: 18/769,151

(22) Filed: Jul. 10, 2024

Related U.S. Application Data
(60) Provisional application No. 63/531,729, filed on Aug. 9, 2023.

(51) Int. Cl. G03F 7/004; G03F 7/075; G03F 7/16; G03F 7/20

(52) U.S. Cl. CPC G03F 7/0043; G03F 7/0752; G03F 7/162; G03F 7/168; G03F 7/2004

(57) ABSTRACT

Embodiments disclosed herein include a method of post development treatment of a metal-oxide photoresist. In an embodiment, a method includes depositing a metal-oxide photoresist over a substrate, exposing the metal-oxide photoresist with an extreme ultra-violet (EUV) exposure to form exposed regions and unexposed regions, developing the exposed metal-oxide photoresist, and performing a surface treatment of the developed metal-oxide photoresist to form a coating on the developed metal-oxide photoresist.

### CROSS-REFERENCE TO RELATED APPLICATIONS

This application claims the benefit of U.S. Provisional Application No. 63/531,729, filed on Aug. 9, 2023, the entire contents of which are hereby incorporated by reference herein.

### BACKGROUND

### 1) Field

Embodiments of the present disclosure pertain to the field of semiconductor processing and, in particular, to methods of performing post development treatment of metal-oxide photoresists.

### 2) Description of Related Art

Lithography has been used in the semiconductor industry for decades for creating 2D and 3D patterns in microelectronic devices. The lithography process involves spin-on deposition of a film (photoresist), irradiation of the film with a selected pattern by an energy source (exposure), and removal (etch) of exposed (positive tone) or non-exposed (negative tone) region of the film by dissolving in a solvent. A bake will be carried out to drive off remaining solvent.

The photoresist should be a radiation sensitive material and upon irradiation a chemical transformation occurs in the exposed part of the film which enables a change in solubility between exposed and non-exposed regions. Using this solubility change, either exposed or non-exposed regions of the photoresist is removed (etched). The photoresist is then developed and the pattern can be transferred to the underlying thin film or substrate by etching. After the pattern is transferred, the residual photoresist is removed and repeating this process many times can give 2D and 3D structures to be used in microelectronic devices.

Several properties are important in lithography processes. Such important properties include sensitivity, resolution, lower line-edge roughness (LER), etch resistance, and ability to form thinner layers. When the sensitivity is higher, the energy required to change the solubility of the as-deposited film is lower. This enables higher efficiency in the lithographic process. Resolution and LER determine how narrow features can be achieved by the lithographic process. Higher etch resistant materials are required for pattern transferring to form deep structures. Higher etch resistant materials also enable thinner films. Thinner films increase the efficiency of the lithographic process.

### SUMMARY

Embodiments disclosed herein include a method of forming a metal-oxide photoresist using a post development treatment process. In an embodiment, a method includes depositing a metal-oxide photoresist over a substrate, exposing the metal-oxide photoresist with an extreme ultra-violet (EUV) exposure to form exposed regions and unexposed regions, developing the exposed metal-oxide photoresist, and performing a surface treatment of the developed metal-oxide photoresist to form a coating on the developed metal-oxide photoresist.

In an embodiment, another method includes depositing a metal-oxide photoresist over a substrate, exposing the metal-oxide photoresist with an extreme ultra-violet (EUV) exposure to form exposed regions and unexposed regions, developing the exposed metal-oxide photoresist, performing a surface treatment of the developed metal-oxide photoresist to form a coating on the developed metal-oxide photoresist, and exposing the coated developed metal-oxide photoresist with an ultra-violet (UV) exposure.

In an embodiment, a system includes a chamber for receiving a developed metal-oxide photoresist thereon, performing a surface treatment of the developed metal-oxide photoresist to form a coating on the developed metal-oxide photoresist, and performing an ultra-violet (UV) exposure of the developed metal-oxide photoresist.

### BRIEF DESCRIPTION OF THE DRAWINGS

FIG. 1A illustrates cross-sectional views representing various operations in a patterning process using a positive tone photo-resist material formed by processes described herein, in accordance with an embodiment of the present disclosure.

FIG. 1B illustrates cross-sectional views representing various operations in a patterning process using a negative tone photo-resist material formed by processes described herein, in accordance with an embodiment of the present disclosure.

FIG. 2 illustrates and angled cross-sectional view of a structure having developed metal-oxide photoresist features with a protective layer or etch resistant layer or surface coating thereon, in accordance with an embodiment of the present disclosure.

FIG. 3 a schematic representing a surface treatment and optional ultra-violet (UV) treatment process, in accordance with an embodiment of the present disclosure.

FIG. 4A illustrates schematics of exemplary precursors (a)-(g) for a metal-oxide photoresist surface treatment and optional ultra-violet (UV) treatment process, e.g., as precursor (b) of FIG. 3, in accordance with an embodiment of the present disclosure.

FIG. 4B illustrates schematics of exemplary precursors (a)-(c) for a metal-oxide photoresist surface treatment and optional ultra-violet (UV) treatment process, e.g., as precursor (b) of FIG. 3, in accordance with an embodiment of the present disclosure.

FIG. 5A illustrates schematics of exemplary precursors (a)-(c) for a metal-oxide photoresist surface treatment and optional ultra-violet (UV) treatment process, e.g., as precursor (b) of FIG. 3, in accordance with an embodiment of the present disclosure.

FIG. 5B illustrates a schematic of an exemplary precursor for a metal-oxide photoresist surface treatment and optional ultra-violet (UV) treatment process, e.g., as precursor (b) of FIG. 3, in accordance with an embodiment of the present disclosure.

FIG. 6 is a cross-sectional illustration of a processing tool that may be used to implement a post development treatment process described herein, in accordance with an embodiment of the present disclosure.

FIG. 7 is a cross-sectional illustration of a processing tool for forming a positive or negative tone metal-oxide photoresist layer over a substrate with a post development treatment process, in accordance with an embodiment of the present disclosure.

FIG. 8 is a zoomed in illustration of an edge of a displaceable column in a processing tool for forming a positive or negative tone metal-oxide photoresist layer over a substrate with a post development treatment process, in accordance with an embodiment of the present disclosure.

FIG. 9A is a zoomed in illustration of an edge of a displaceable column in a processing tool, where the shadow ring is not engaged with the edge ring, in accordance with an embodiment of the present disclosure.

FIG. 9B is a zoomed in illustration of an edge of a displaceable column in a processing tool, where the shadow ring is engaged with the edge ring, in accordance with an embodiment of the present disclosure.

FIG. 10A is a sectional view of a processing tool for forming a positive or negative tone metal-oxide photoresist layer over a substrate with a post development treatment process, in accordance with an embodiment of the present disclosure.

FIG. 10B is a sectional view of a processing tool with the pedestal removed to expose the channels in a baseplate, in accordance with an embodiment of the present disclosure.

FIG. 11 illustrates a block diagram of an exemplary computer system, in accordance with an embodiment of the present disclosure.

### DETAILED DESCRIPTION

Methods of post development processing of a positive or negative tone metal-oxide photoresist are described herein. In the following description, numerous specific details are set forth, such as chemical vapor deposition (CVD) and atomic layer deposition (ALD) processes and material regimes for depositing a positive or negative tone metal-oxide photoresist, in order to provide a thorough understanding of embodiments of the present disclosure. It will be apparent to one skilled in the art that embodiments of the present disclosure may be practiced without these specific details. In other instances, well-known aspects, such as integrated circuit fabrication, are not described in detail in order to not unnecessarily obscure embodiments of the present disclosure. Furthermore, it is to be understood that the various embodiments shown in the Figures are illustrative representations and are not necessarily drawn to scale.

To provide context, photoresist systems used in extreme ultraviolet (EUV) lithography suffer from low efficiency. That is, existing photoresist material systems for EUV lithography require high dosages in order to provide the needed solubility switch that allows for developing the photoresist material. Traditionally, carbon based films called organic chemically amplified photoresists (CAR) have been used as a photoresist. However, more recently organic-inorganic hybrid materials (metal-oxo) have been used as a photoresist with extreme ultraviolet (EUV) radiation. Such materials typically include a metal (such as Sn, Hf, Zr), oxygen, and carbon. Transformation from deep UV (DUV) to EUV in the lithographic industry facilitated narrow features with high aspect ratio. Metal-oxo based organic-inorganic hybrid materials have been shown to exhibit lower line edge roughness (LER) and higher resolution which are required for forming narrow features. Also, such films have higher sensitivity and etch resistance properties and can be implemented to fabricate relatively thinner films.

In accordance with one or more embodiments of the present disclosure, post develop treatment of a metal-oxide photoresist is described. In an embodiment, post develop treatment of a metal-oxide photoresist with selective passivation plus UV irradiation is described.

Currently, etch selectivity, line edge roughness (LER), line width roughness (LWR), and photoresist outgas induced cross-contamination can be issues associated with metal-oxide photoresists. Advantages to implementing embodiments described herein can include improved etch selectivity, reduced line edge roughness (LER), reduced line width roughness (LWR), and/or reduced photoresist outgas induced cross-contamination.

To provide context, during pattern transfer, etch selectivity between a metal-oxide photoresist and an underlying layer or substrate during pattern transfer etch needs to be improved. LWR/LER of the etched pattern needs to be improved.

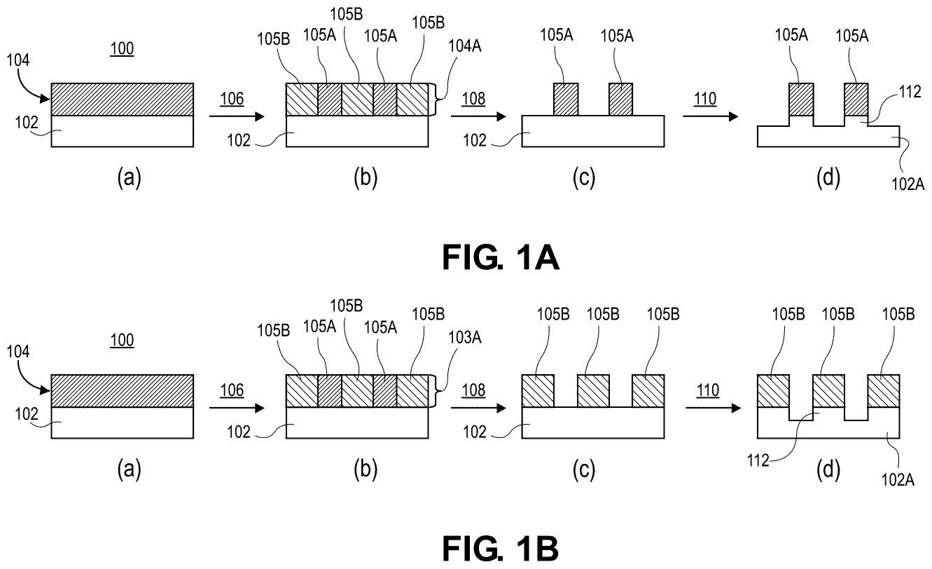

To provide further background, FIG. 1A illustrates cross-sectional views representing various operations in a patterning process using a positive tone photo-resists material formed by processes described herein, in accordance with an embodiment of the present disclosure.

Referring to part (a) of FIG. 1A, a starting structure 100 includes a positive tone photoresist layer 104 above a substrate or underlying layer 102. In one embodiment, the positive tone photoresist layer 104 is deposited using dry deposition. Referring to part (b) of FIG. 1A, the starting structure 100 is irradiated 106 in select locations to form an irradiated photoresist layer 104A having irradiated regions 105B and non-irradiated regions 105A. Referring to part (c) of FIG. 1A, a removal or etch process 108 is used to provide a developed photoresist layer of non-irradiated regions 105A. Referring to part (d) of FIG. 1A, an etch process 110 using the non-irradiated regions 105A as a mask is used to pattern the substrate or underlying layer 102 to form patterned substrate or patterned underlying layer 102A including etched features 112.

Referring again to FIG. 1A, the positive tone photoresist 104 is a radiation sensitive material and, upon irradiation, a chemical transformation occurs in the exposed part of the film which enables a change in solubility between exposed and non-exposed regions. Using the solubility change, exposed regions of the positive tone photoresist are removed (etched). The positive tone photoresist is then developed and the pattern can be transferred to the underlying thin film or substrate by etching. After the pattern is transferred, the residual positive tone photoresist is removed. The process can be repeated many times can fabricate 2D and 3D structures, e.g., for use in microelectronic devices.

To provide further background, FIG. 1B illustrates cross-sectional views representing various operations in a patterning process using a negative tone photo-resists material formed by processes described herein, in accordance with an embodiment of the present disclosure.

Referring to part (a) of FIG. 1B, a starting structure 100 includes a negative tone photoresist layer 103 above a substrate or underlying layer 102. In one embodiment, the negative tone photoresist layer 103 is deposited using dry deposition. Referring to part (b) of FIG. 1B, the starting structure 100 is irradiated 106 in select locations to form an irradiated photoresist layer 103A having irradiated regions 105B and non-irradiated regions 105A. Referring to part (c) of FIG. 1B, a removal or etch process 108 is used to provide a developed photoresist layer of irradiated regions 105B. Referring to part (d) of FIG. 1B, an etch process 110 using the irradiated regions 105B as a mask is used to pattern the substrate or underlying layer 102 to form patterned substrate or patterned underlying layer 102A including etched features 112.

Referring again to FIG. 1B, the negative tone photoresist 103 is a radiation sensitive material and, upon irradiation, a chemical transformation occurs in the exposed part of the film which enables a change in solubility between exposed and non-exposed regions. Using the solubility change, unexposed regions of the negative tone photoresist are removed (etched). The negative tone photoresist is then developed and the pattern can be transferred to the underlying thin film or substrate by etching. After the pattern is transferred, the residual negative tone photoresist is removed. The process can be repeated many times can fabricate 2D and 3D structures, e.g., for use in microelectronic devices.

As will be described in greater detail below, the positive tone resist and the negative tone resist may both be metal-oxide photoresist films. In some instances the same material system may be used for the both the positive tone resist and the negative tone resist. That is, dry deposition with an EUV exposure may be used to form either positive tone or negative tone resists. In other embodiments, wet deposition can be used.

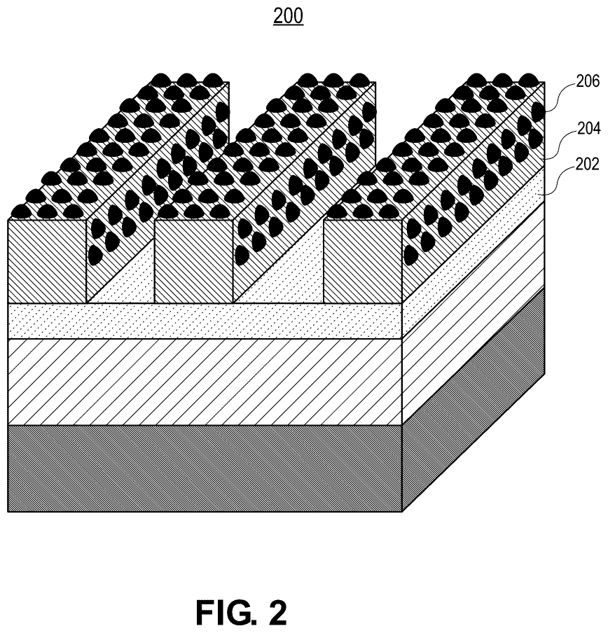

In accordance with one or more embodiments of the present disclosure, following development of a metal-oxide photo resist, a protective layer or etch resistant layer or surface coating is formed on the developed resist features. The protective layer or etch resistant layer or surface coating can enhance the etch selectivity of the etch process used to pattern an under layer or substrate using the developed resist features as a mask. As an exemplary structure, FIG. 2 illustrates and angled cross-sectional view of a structure having developed metal-oxide photoresist features with a protective layer or etch resistant layer or surface coating thereon, in accordance with an embodiment of the present disclosure.

Referring to FIG. 2, a structure 200 includes an under layer 202 which can be a single under layer, a stack of under layers, or an under layer on a substrate. In one embodiment, the under layer 202 is a spin on glass layer, an SiC layer, or an SiN layer. In one embodiment, the under layer 202 does not have terminal-OH ligands. Developed metal-oxide photoresist features 204, such as positive or negative tone features, is formed on the under layer 202. A protective layer or etch resistant layer or surface coating 206 is formed on developed metal-oxide photoresist features 204.

In accordance with one or more embodiments of the present disclosure, a process flow is performed according to: (1) metal-oxide photoresist deposition, such as spin on or dry deposition, (2) pre-treatment, such as thermal bake, plasma treatment, or UV treatment, (3) extreme ultraviolet (EUV) exposure as a lithography process, (4) post treatment, such as a thermal bake, plasma treatment, or UV treatment, (5) development of the metal-oxide PR, which can be a wet or dry develop process, (6) post develop treatment, such as (a) surface treatment only, or (b) surface treatment plus ultra-violet (UV) treatment process, (7) pattern transfer etch, e.g., with improved etch selectivity and improved LER/LWR.

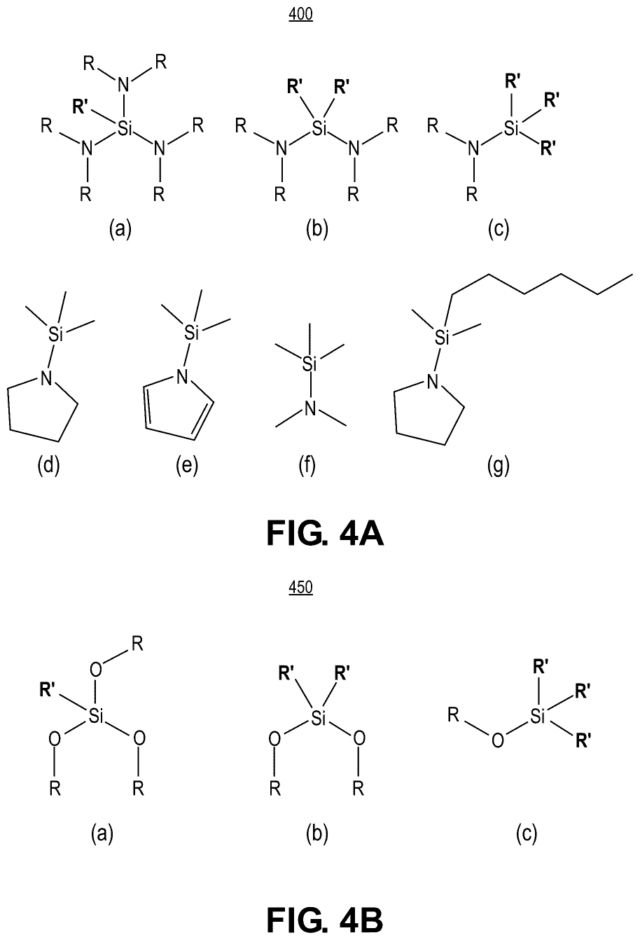

In accordance with an embodiment of the present disclosure, referring to part (6)(a) above, a surface treatment only process can be performed at a temperature in the range of 20-500 degrees Celsius, a pressure in the range of 10 mTorr to 500 Torr, a chemical flow in the range of 100 mg/min to 5000 mg/min, with an inert carrier gas of Ar, N₂ or He, and with a precursor of FIG. 4A, 4B, 5A or 5B, described below.

In accordance with an embodiment of the present disclosure, referring to part (6)(b) above, a surface treatment plus ultra-violet (UV) treatment process can be performed at a temperature in the range of 20-500 degrees Celsius, a pressure in the range of 10 mTorr to 500 Torr, a chemical flow in the range of 100 mg/min to 5000 mg/min, with an inert carrier gas of Ar, N₂ or He, with a precursor of FIG. 4A, 4B, 5A or 5B, described below, and with a UV exposure with a UV wavelength in the range of 150-500 nm.

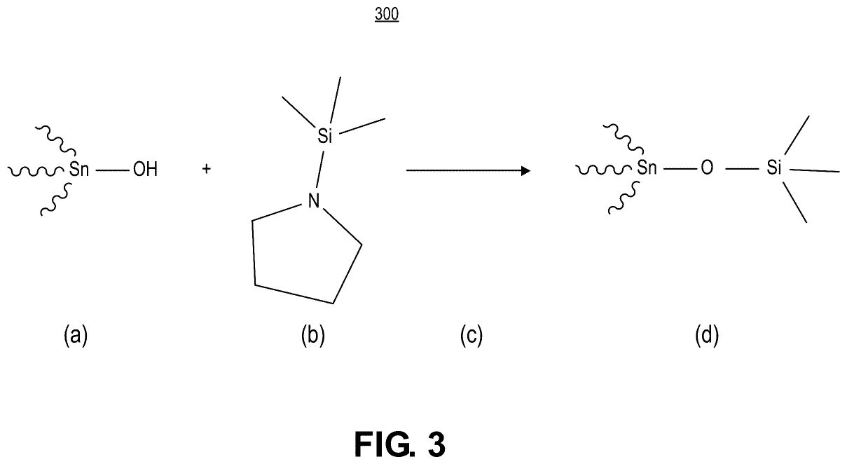

As an exemplary treatment scheme, FIG. 3 a schematic representing a surface treatment and optional ultra-violet (UV) treatment process 300, in accordance with an embodiment of the present disclosure.

Referring to FIG. 3, a metal-oxide photoresist with OH surface dangling bonds (a) is treated with a precursor (b, with an exemplary precursor shown) which can be a thermal passivation precursor. The treatment (c) may further include exposure to UV radiation. In either case, the result is a metal-oxide photoresist with surface passivation (d).

FIG. 4A illustrates schematics 400 of exemplary precursors (a)-(g) for a metal-oxide photoresist surface treatment and optional ultra-violet (UV) treatment process, e.g., as precursor (b) of FIG. 3, in accordance with an embodiment of the present disclosure. R can be independently selected from Me, Et, iPr, tBu, H. R′ can be independently selected from alkane, alkene, alkyne, which can be based on, e.g., C1-C20 structures.

FIG. 4B illustrates schematics 450 of exemplary precursors (a)-(c) for a metal-oxide photoresist surface treatment and optional ultra-violet (UV) treatment process, e.g., as precursor (b) of FIG. 3, in accordance with an embodiment of the present disclosure. R can be independently selected from Me, Et, iPr, tBu. R′ can be independently selected from alkane, alkene, alkyne, which can be based on, e.g., C1-C20 structures.

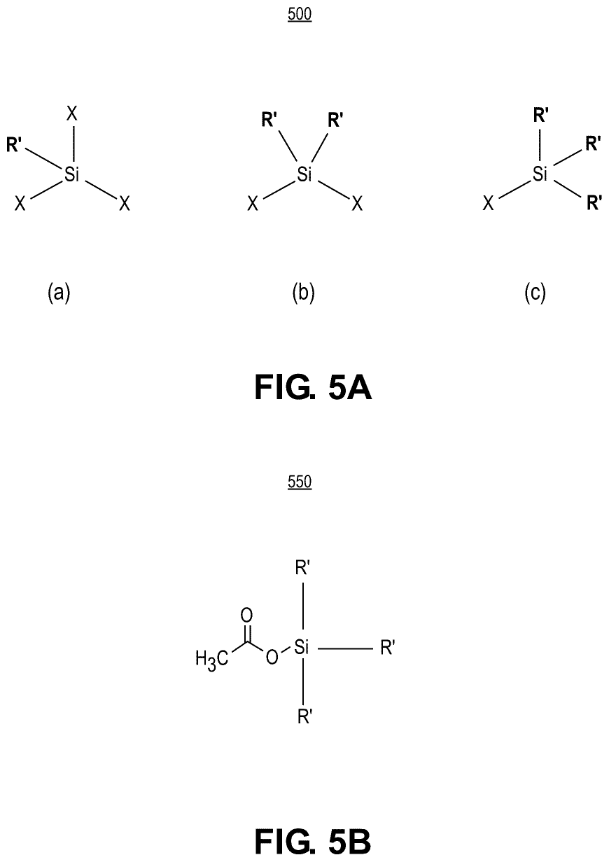

FIG. 5A illustrates schematics 500 of exemplary precursors (a)-(c) for a metal-oxide photoresist surface treatment and optional ultra-violet (UV) treatment process, e.g., as precursor (b) of FIG. 3, in accordance with an embodiment of the present disclosure. X can be independently selected from Cl, Br, I. R′ can be independently selected from alkane, alkene, alkyne, which can be based on, e.g., C1-C20 structures.

FIG. 5B illustrates a schematic 550 of an exemplary precursor for a metal-oxide photoresist surface treatment and optional ultra-violet (UV) treatment process, e.g., as precursor (b) of FIG. 3, in accordance with an embodiment of the present disclosure. R′ can be independently selected from alkane, alkene, alkyne, which can be based on, e.g., C1-C20 structures.

Not to be bound by theory, it is understood that the surface treatment can passivate OH-bonding on the surface of a metal-oxide photoresist after develop, in order to enhance the etch selectivity between a photoresist mask and an under layer or substrate during pattern transfer etch. UV irradiation may be able to enhance the chemical reaction of molecule and PR—OH bond during the surface passivation process. UV irradiation may also smoothen and densify the metal-oxide photoresist. A combination of surface treatment and UV treatment may stabilize the photoresist by passivating, smoothening and densifying the metal-oxide photoresist in order to reduce outgas of the metal-oxide photoresist and thus reduce the cross contamination from metal-oxide photoresist outgas. Advantages for implementing embodiments described herein can also include improving the LER/LWR during pattern transfer etch.

In accordance with an embodiment of the present disclosure, a positive tone or negative tone photoresist is fabricated by using a particular type of R group in the metal precursor or plasma assisted deposition methods. It is to be appreciated that the lithography industry is typically used to dealing with positive tone PRs, however almost all of the novel metal-oxo PRs are negative tone PRs. Embodiments described herein can be implemented for post development treatment of both positive tone PRs and negative tone PRs.

In another aspect, for an exposure environment, when the photoresist is exposed by an energy source (e.g., EUV) the exposure chamber (environment) can be oxygen-containing or inert. In one embodiment, exposure is under vacuum with an oxygen source such as O₂, H₂O, CO₂, CO, NO₂, or NO. A repetition of EUV exposure and then oxygen exposure can be, in one embodiment, between 1 and 100 times.

In another aspect, post anneal is performed in an oxygen-containing environment. In one embodiment, the oxygen source is O₃, NO₂, NO or O₂, which can be used to form a plasma, and/or which can be used along with N₂, Ar or He. In one embodiment, the post anneal is performed at a temperature in the range of 25-200 degrees Celsius. In one embodiment, the post anneal is performed at a pressure of less than 200 torr. In a particular embodiment, the post anneal is performed using ozone (O₃) as an oxygen source gas, at a temperature in the range of 25-250 degrees Celsius, at a pressure less than 200 torr.

Regarding deposition of a metal-oxide photoresist, in accordance with an embodiment of the present disclosure, in a first approach a chemical vapor deposition (CVD) method for forming a positive tone or negative tone photoresist includes: (A) One or more metal precursors and one or more oxidants are vaporized to a vacuum chamber where a substrate wafer is maintained at a pre-determined substrate temperature. Substrate temperature can vary from 0 C to 500 C. When the precursors/oxidants are vaporized to the chamber, they can be diluted with inert gases such as Ar, N₂, He. Due to the reactivity of the precursor and oxidant, metal-oxo film is deposited on the wafer. Vaporization to the chamber can be performed by all precursors simultaneously or alternative pulsing of metal precursor(s) and oxidant(s). This process can be described as thermal CVD. (B) Plasma can be turned on during this process as well, and then the process can be described as plasma enhanced (PE)-CVD. Examples of plasma sources are CCP, ICP, remote plasma, microwave plasma. (C) Photoresist film deposition can be performed by thermal deposition followed by plasma treatment. In this case, film is deposited thermally and then a plasma treatment operation is performed. Plasma treatment may involve plasma from inert gasses such as Ar, N₂, He or those gasses can be mixed with O₂, CO₂, CO, NO, NO₂, H₂O. The processes can be carried out as in cyclic fashion; thermal deposition followed by plasma treatment and repeat this cycle or complete the deposition part and then do one plasma treatment (post treatment). PECVD followed by plasma treatment is also possible. In either case, in an embodiment, a post anneal in an oxygen-containing environment is performed. In one embodiment, the post anneal is performed using ozone (O₃) as an oxygen source gas, at a temperature in the range of 25-250 degrees Celsius, at a pressure less than 200 torr.

In a second approach, in accordance with an embodiment of the present disclosure, an atomic layer deposition (ALD) method for forming a positive tone or negative tone photoresist includes: (A) A metal precursor from is vaporized to an vacuum chamber where a substrate wafer is maintained at a pre-determined substrate temperature. Substrate temperature can vary from 0 to 500 C. Then, an inter gas purge is provided to remove by-products and excess metal precursor. Then, one or more oxidant is vaporized to the chamber. The oxidant(s) react with surface absorbed metal precursor. Then, an inert gas purge is applied to remove the by-products and unreacted oxidant. This cycle can be repeated to get to the desired thickness. When the precursor or oxidant is vaporized to the chamber, it can be diluted with inert gases such as Ar, N₂, He. This process can be described as thermal ALD. Using this method more than one metal can be incorporated into the film by incorporating additional metal precursor pulses to a ALD cycle. Also, a different oxidant can be pulsed after the first oxidant. (B) A plasma can be turned on during the oxidant pulse and then the process can be described as PE-ALD. (C) Also, the deposition can be performed by thermal ALD followed by plasma treatment. In this case, film is deposited by thermally and then a plasma treatment operation is carried out. Plasma treatment may involve plasma from inert gasses such as Ar, N₂, He or those gasses can be mixed with O₂, CO₂, CO, NO, NO₂, H₂O. The processes can be performed as in cyclic fashion; X number of thermal ALD cycles (X=1-5000) followed by plasma treatment and repeat the whole cycle for desired number of times, or complete the deposition part and then do one plasma treatment. PE-ALD followed by plasma treatment is also possible. In either case, in an embodiment, a post anneal in an oxygen-containing environment is performed. In one embodiment, the post anneal is performed using ozone (O₃) as an oxygen source gas, at a temperature in the range of 25-250 degrees Celsius, at a pressure less than 200 torr.

In a third approach, in accordance with an embodiment of the present disclosure, an atomic layer deposition (ALD) or chemical vapor deposition (CVD) method for forming a positive tone or negative tone photoresist includes providing a composition gradient throughout the film. As an example, the first few nanometers of the film have a different composition than the rest of the film. The main portion of the film can be optimized for dose, but target a different composition close to the interface layer to change adhesion, sensitivity to EUV photons, sensitivity to develop chemistry in order to improve post lithography profile control (especially scumming) as well as defectivity and resist collapse/lift off. The gradation might be optimized for pattern type, for example pillars needing improved adhesion vs line/space patterns being able to lower adhesion for improvements in dose.

In an embodiment, photoresist film deposition methods described here are vacuum deposition methods that do not involve wet chemistry. Positive tone or negative tone photoresists described herein have advantages such as higher resolution, higher dry etch resistance, and higher contrast than negative tone photoresists.

Advantages to implementing one or more of the approaches described herein can include that the positive tone or negative tone photoresist film deposition approaches are dry deposition approaches and do not involve wet chemistry. Wet chemistry methods can generate a substantial amount of wet by-products which may be preferable to avoid. Also, spin-on (wet methods) often lead to non-uniformity issues which can be successfully addressed by vacuum deposition methods described herein. Also, the percentage of metal and carbon (C) in the film can be tuned by vacuum deposition method. In spin-on, metal percentage and C are often fixed in a given deposition system. Precursors used for depositing positive tone or negative tone photoresist films under vacuum need to be volatile, and the precursors described herein are volatile based on L and R structure. Dry deposition methods may require lower temperatures than other vacuum deposition methods such as ALD or CVD. When the deposition is performed at low temperatures, relatively higher amounts of carbon can be retained in the film, which can be helpful in patterning.

In an embodiment, a vacuum deposition process relies on chemical reactions between a metal precursor and an oxidant. The metal precursor and the oxidant are vaporized to a vacuum chamber. In some embodiments, the metal precursor and the oxidant are provided to the vacuum chamber together. In other embodiments, the metal precursor and the oxidant are provided to the vacuum chamber with alternating pulses. After a metal-oxo positive or negative tone photoresist film with a desired thickness is formed, the process may be halted. In an embodiment, an optional plasma treatment operation may be executed after a metal-oxo positive or negative tone photoresist film with a desired thickness is formed.

In an embodiment, a cycle including a pulse of the metal precursor vapor and a pulse of the oxidant vapor may be repeated a plurality of times to provide a metal-oxo positive or negative tone photoresist film with a desired thickness. In an embodiment, the order of the cycle may be switched. For example, the oxidant vapor may be pulsed first and the metal precursor vapor may be pulsed second. In an embodiment, a pulse duration of the metal precursor vapor may be substantially similar to a pulse duration of the oxidant vapor. In other embodiments, the pulse duration of the metal precursor vapor may be different than the pulse duration of the oxidant vapor. In an embodiment, the pulse durations may be between 0 seconds and 1 minute. In a particular embodiment, the pulse durations may be between 1 second and 5 seconds. In an embodiment, each iteration of the cycle uses the same processing gasses. In other embodiments, the processing gasses may be changed between cycles. For example, a first cycle may utilize a first metal precursor vapor, and a second cycle may utilize a second metal precursor vapor. Subsequent cycles may continue alternating between the first metal precursor vapor and the second metal precursor vapor. In an embodiment, multiple oxidant vapors may be alternated between cycles in a similar fashion. In an embodiment, an optional plasma treatment of operation may be executed after every cycle. That is, each cycle may include a pulse of metal precursor vapor, a pulse of oxidant vapor, and a plasma treatment. In an alternate embodiment, an optional plasma treatment of operation may be executed after a plurality of cycles. In yet another embodiment, an optional plasma treatment operation may be executed after the completion of all cycles (i.e., as a post treatment).

Providing metal-oxo positive tone and negative tone photoresist films using dry deposition and oxidation treatment processes such as described in the embodiments above can achieve significant advantages over wet chemistry methods. One such advantage is the elimination of wet byproducts. With a dry deposition process, liquid waste is eliminated and byproduct removal is simplified. Additionally, dry deposition processes can provide a more uniform positive tone and negative tone photoresist layers. Uniformity in this sense may refer to thickness uniformity across the wafer and/or uniformity of the distribution of metal components of the metal-oxo film.

Additionally, the use of dry deposition processes provides the ability to fine-tune the percentage of metal in the positive tone or negative tone photoresist and the composition of the metal in the positive tone or negative tone photoresist. The percentage of the metal may be modified by increasing/decreasing the flow rate of the metal precursor into the vacuum chamber and/or by modifying the pulse lengths of the metal precursor/oxidant. The use of a dry deposition process also allows for the inclusion of multiple different metals into the metal-oxo film. For example, a single pulse flowing two different metal precursors may be used, or alternating pulses of two different metal precursors may be used.

Furthermore, it has been shown that metal-oxo positive tone and negative tone photoresists that are formed using dry deposition processes are more resistant to thickness reduction after exposure. It is believed, without being tied to a particular mechanism, that the resistance to thickness reduction is attributable, at least in part, to the reduction of carbon loss upon exposure.

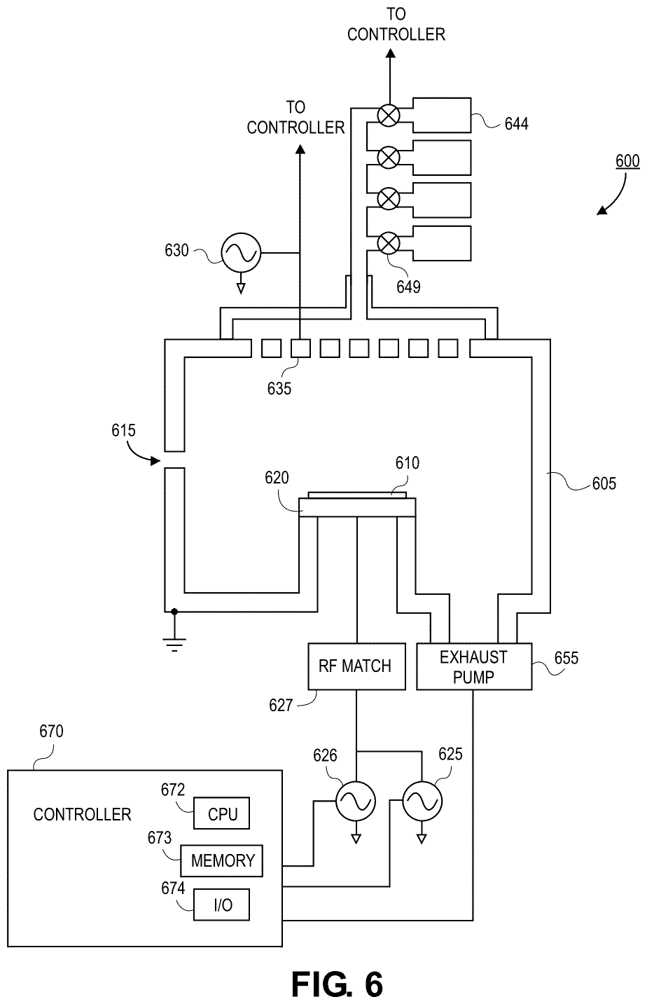

In an embodiment, a vacuum chamber utilized in a post development treatment process is any suitable chamber capable of providing a sub-atmospheric pressure. In an embodiment, the vacuum chamber may include temperature control features for controlling chamber wall temperatures and/or for controlling a temperature of the substrate. In an embodiment, the vacuum chamber may also include features for providing a plasma within the chamber. A more detailed description of a suitable vacuum chamber is provided below with respect to FIG. 6. FIG. 6 is a schematic of a vacuum chamber configured to perform a post development treatment of a metal-oxo photoresist, in accordance with an embodiment of the present disclosure.

Vacuum chamber 600 includes a grounded chamber 605. A substrate 610 is loaded through an opening 615 and clamped to a temperature controlled chuck 620. In an embodiment, the substrate 610 may be temperature controlled during a post development treatment process. For example, the temperature of the substrate 610 may be between approximately −40 degrees Celsius to 200 degrees Celsius. In a particular embodiment, the substrate 610 may be held to a temperature between room temperature and 150° C.

Process gases, are supplied from gas sources 644 through respective mass flow controllers 649 to the interior of the chamber 605. In certain embodiments, a gas distribution plate 635 provides for distribution of process gases 644, such as a ligand and an inert gas. Chamber 605 is evacuated via an exhaust pump 655. In one embodiment, one or more of the process gases are contained/stored in one or more ampoules. In one embodiment, the dry deposition process is a chemical vapor condensation process, and the one or more ampoules are maintained at a temperature above the substrate temperature, such as at a temperature 25 degrees Celsius or greater than the substrate temperature. In one or more embodiments, a post development treatment, such as described above, is then performed.

When RF power is applied during processing of a substrate 610, a plasma is formed in chamber processing region over substrate 610. Bias power RF generator 625 is coupled to the temperature controlled chuck 620. Bias power RF generator 625 provides bias power, if desired, to energize the plasma. Bias power RF generator 625 may have a low frequency between about 2 MHz to 60 MHz for example, and in a particular embodiment, is in the 13.56 MHz band. In certain embodiments, the vacuum chamber 600 includes a third bias power RF generator 626 at a frequency at about the 2 MHz band which is connected to the same RF match 627 as bias power RF generator 625. Source power RF generator 630 is coupled through a match (not depicted) to a plasma generating element (e.g., gas distribution plate 635) to provide a source power to energize the plasma. Source RF generator 630 may have a frequency between 100 and 180 MHz, for example, and in a particular embodiment, is in the 162 MHz band. Because substrate diameters have progressed over time, from 150 mm, 200 mm, 300 mm, etc., it is common in the art to normalize the source and bias power of a plasma etch system to the substrate area.

The vacuum chamber 600 is controlled by controller 670. The controller 670 may include a CPU 672, a memory 673, and an I/O interface 674. The CPU 672 may execute processing operations within the vacuum chamber 600 in accordance with instructions stored in the memory 673. For example, one or more processes such as processes 120 and 440 described above may be executed in the vacuum chamber by the controller 670.

In another aspect, embodiments disclosed herein include a processing tool that includes an architecture that is particularly suitable for optimizing post development treatment. For example, the processing tool may include a pedestal for supporting a wafer that is temperature controlled. In some embodiments, a temperature of the pedestal may be maintained between approximately −40° C. and approximately 200° C. Additionally, an edge purge flow and shadow ring may be provided around a perimeter of the column on which the substrate is supported. The edge purge flow and shadow ring prevent the positive or negative tone metal-oxide photoresist from depositing along the edge or backside of the wafer. In an embodiment, the pedestal may also provide any desired chucking architecture, such as, but not limited to vacuum chucking, monopolar chucking, or bipolar chucking, depending on the operating regime of the processing tool.

In some embodiments, the processing tool may be suitable for deposition processes without a plasma. Alternatively, the processing tool may include a plasma source to enable plasma enhanced operations. Furthermore, while embodiments disclosed herein are particularly suitable for the deposition of metal-oxo positive or negative tone photoresists for EUV patterning, it is to be appreciated that embodiments are not limited to such configurations. For example, the processing tools described herein may be suitable for depositing any positive or negative tone photoresist material for any regime of lithography using a post development treatment process.

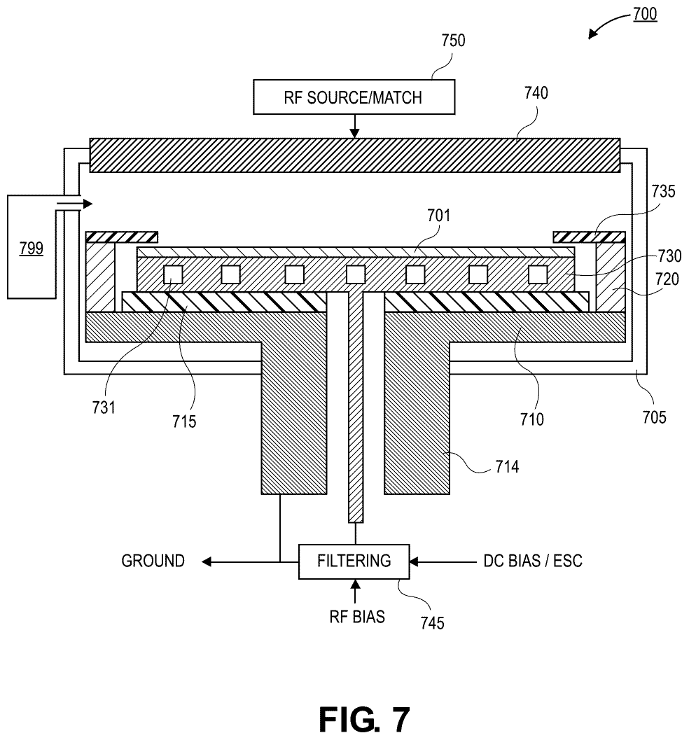

Referring now to FIG. 7, a cross-sectional illustration of a processing tool 700 is shown, in accordance with an embodiment. In an embodiment, the processing tool 700 may include a chamber 705. The chamber 705 may be any suitable chamber capable of supporting a sub-atmospheric pressure (e.g., a vacuum pressure). In an embodiment, an exhaust (not shown) that includes a vacuum pump may be coupled to the chamber 705 to provide a sub-atmospheric pressure. In an embodiment, a lid may seal the chamber 705. For example, the lid may include a showerhead assembly 740 or the like. The showerhead assembly 740 may include fluidic pathways to enable processing gasses and/or inert gasses to be flown into the chamber 705. In some embodiments where the processing tool 700 is suitable for plasma enhanced operation, the showerhead assembly 740 may be electrically coupled to an RF source and matching circuitry 750. In yet another embodiment, the tool 700 may be configured in an RF bottom fed architecture. That is, the pedestal 730 is connected to an RF source, and the showerhead assembly 740 is grounded. In such an embodiment, the filtering circuitry may still be connected to the pedestal. In one embodiment, a precursor gas is stored in an ampoule 799.

In an embodiment, a displaceable column for supporting a wafer 701 is provided in the chamber 705. In an embodiment, the wafer 701 may be any substrate on which a positive or negative tone metal-oxide photoresist material is deposited. For example, the wafer 701 may be a 300 mm wafer or a 450 mm wafer, though other wafer diameters may also be used. Additionally, the wafer 701 may be replaced with a substrate that has a non-circular shape in some embodiments. The displaceable column may include a pillar 714 that extends out of the chamber 705. The pillar 714 may have a port to provide electrical and fluidic paths to various components of the column from outside the chamber 705.

In an embodiment, the column may include a baseplate 710. The baseplate 710 may be grounded. As will be described in greater detail below, the baseplate 710 may include fluidic channels to allow for the flow of an inert gas to provide an edge purge flow.

In an embodiment, an insulating layer 715 is disposed over the baseplate 710. The insulating layer 715 may be any suitable dielectric material. For example, the insulating layer 715 may be a ceramic plate or the like. In an embodiment, a pedestal 730 is disposed over the insulating layer 715. The pedestal 730 may include a single material or the pedestal 730 may be formed from different materials. In an embodiment, the pedestal 730 may utilize any suitable chucking system to secure the wafer 701. For example, the pedestal 730 may be a vacuum chuck or a monopolar chuck. In embodiments where a plasma is not generated in the chamber 705, the pedestal 730 may utilize a bipolar chucking architecture.

The pedestal 730 may include a plurality of cooling channels 731. The cooling channels 731 may be connected to a fluid input and a fluid output (not shown) that pass through the pillar 714. In an embodiment, the cooling channels 731 allow for the temperature of the wafer 701 to be controlled during operation of the processing tool 700. For example, the cooling channels 731 may allow for the temperature of the wafer 701 to be controlled to between approximately −40° C. and approximately 200° C. In an embodiment, the pedestal 730 connects to the ground through filtering circuitry 745, which enables DC and/or RF biasing of the pedestal with respect to the ground.

In an embodiment, an edge ring 720 surrounds a perimeter of the insulating layer 715 and the pedestal 730. The edge ring 720 may be a dielectric material, such as a ceramic. In an embodiment, the edge ring 720 is supported by the base plate 710. The edge ring 720 may support a shadow ring 735. The shadow ring 735 has an interior diameter that is smaller than a diameter of the wafer 701. As such, the shadow ring 735 blocks the positive or negative tone metal-oxide photoresist from being deposited onto a portion of the outer edge of the wafer 701. A gap is provided between the shadow ring 735 and the wafer 701. The gap prevents the shadow ring 735 from contacting the wafer 701, and provides an outlet for the edge purge flow that will be described in greater detail below. In an embodiment, a dual channel showerhead can be used for a positive or negative tone metal-oxide photoresist fabrication process.

While the shadow ring 735 provides some protection of the top surface and edge of the wafer 701, processing gasses may flow/diffuse down along a path between the edge ring 720 and the wafer 701. As such, embodiments disclosed herein may include a fluidic path between the edge ring 720 and the pedestal 730 to enable an edge purge flow. Providing an inert gas in the fluidic path increases the local pressure in the fluidic path and prevents processing gasses from reaching the edge of the wafer 701. Therefore, deposition of the positive or negative tone metal-oxide photoresist is prevented along the edge of the wafer 701.

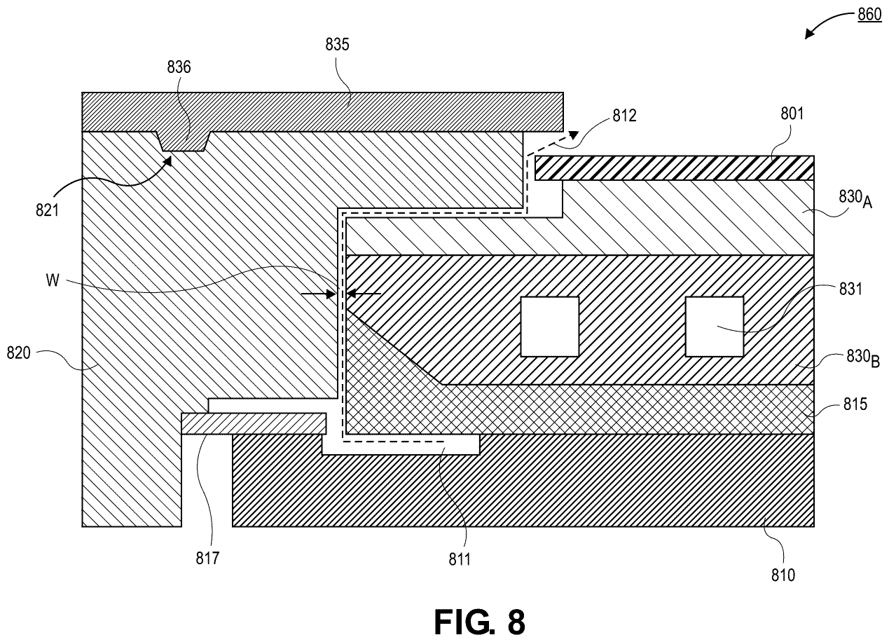

Referring now to FIG. 8, a zoomed in cross-sectional illustration of a portion of a column 860 within a processing tool is shown, in accordance with an embodiment. In FIG. 8, only the left edge of the column 860 is shown. However, it is to be appreciated that the right edge of the column 860 may substantially mirror the left edge.

In an embodiment, the column 860 may include a baseplate 810. An insulating layer 815 may be disposed over the baseplate 810. In an embodiment, the pedestal 830 may include a first portion 830A and a second portion 830B. The cooling channels 831 may be disposed in the second portion 830B. The first portion 830A may include features for chucking the wafer 801.

In an embodiment, an edge ring 820 surrounds the baseplate 810, the insulating layer 815, the pedestal 830, and the wafer 801. In an embodiment, the edge ring 820 is spaced away from the other components of the column 850 to provide a fluidic path 812 from the baseplate 810 to the topside of the column 860. For example, the fluidic path 812 may exit the column between the wafer 801 and shadow ring 835. In a particular embodiment, an interior surface of the fluidic path 812 includes an edge of the insulating layer 815, an edge of the pedestal 830 (i.e., the first portion 830A and the second portion 830B), and an edge of the wafer 801. In an embodiment, the outer surface of the fluidic path 812 includes an interior edge of the edge ring 820. In an embodiment, the fluidic path 812 may also continue over a top surface of a portion of the pedestal 830 as it progresses to the edge of the wafer 801. As such, when an inert gas (e.g., helium, argon, etc.) is flown through the fluidic path 812, processing gasses are prevented from flowing/diffusing down the side of the wafer 801.

In an embodiment, the width W of the fluidic path 812 is minimized in order to prevent the striking of a plasma along the fluidic path 812. For example, the width W of the fluidic path 812 may be approximately 1 mm or less. In an embodiment, a seal 817 blocks the fluidic path 812 from exiting the bottom of the column 860. The seal 817 may be positioned between the edge ring 820 and the baseplate 810. The seal 817 may be a flexible material, such as a gasket material or the like. In a particular embodiment, the seal 817 includes silicone.

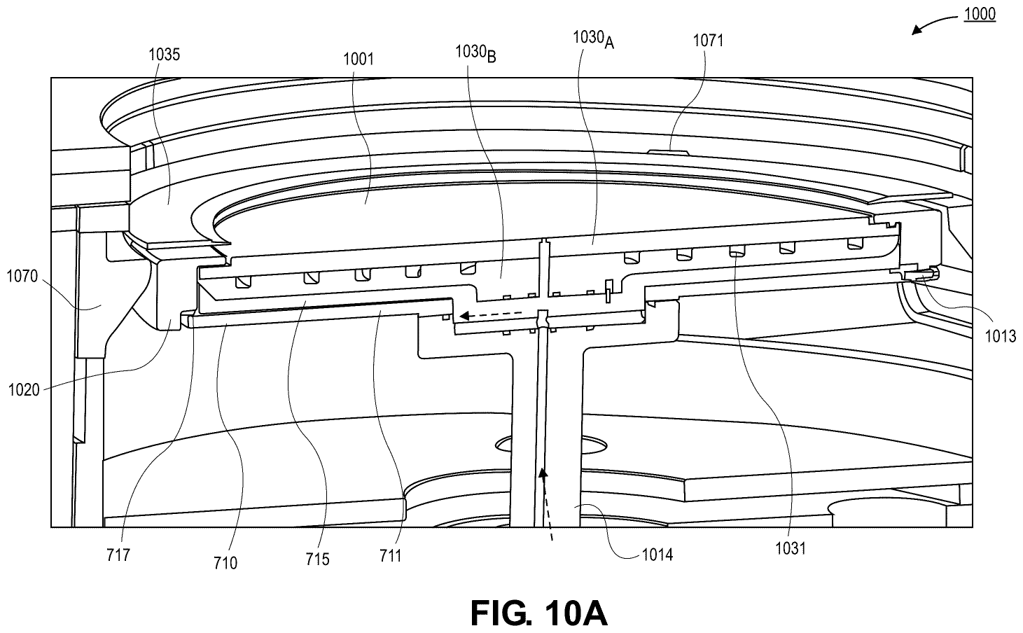

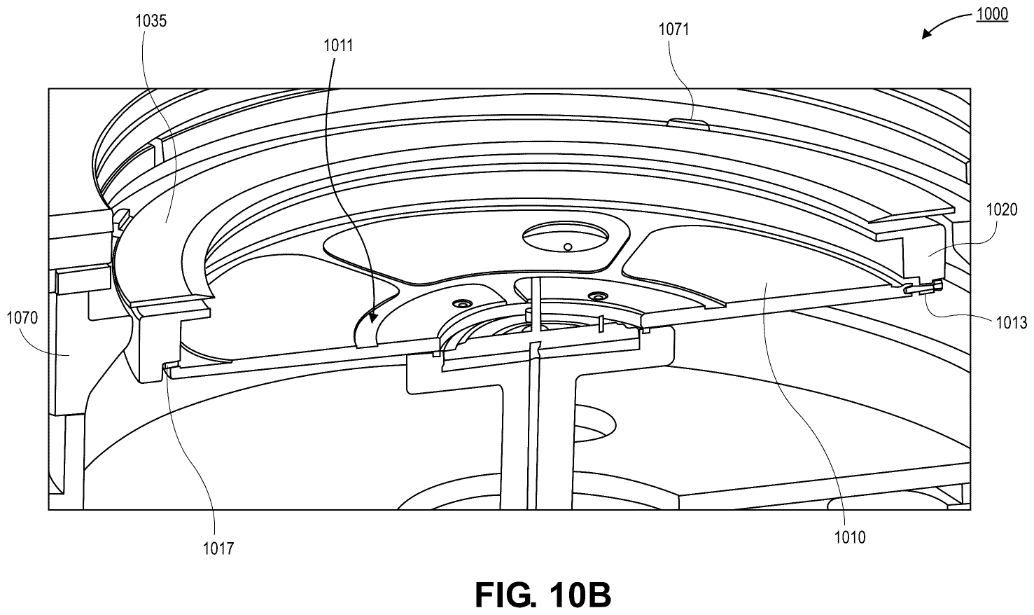

In an embodiment, a channel 811 is disposed in the baseplate 810. The channel 811 routes an inert gas from the center of the column 860 to the interior edge of the edge ring 820. It is to be appreciated that only a portion of the channel 811 is illustrated in FIG. 8. A more comprehensive illustration of the channel 811 is provided below with respect to FIG. 10B.

In an embodiment, the edge ring 820 and the shadow ring 835 may have features suitable for aligning the shadow ring 835 with respect to the wafer 801. For example, a notch 821 in the top surface of the edge ring 820 may interface with a protrusion 836 on the bottom surface of the shadow ring 835. The notch 821 and protrusion 836 may have tapered surfaces to allow for coarse alignment of the two components to be sufficient to provide a more precise alignment as the edge ring 820 is brought into contact with the shadow ring 835. In an additional embodiment, an alignment feature (not shown) may also be provided between the pedestal 830 and the edge ring 820. The alignment feature between the pedestal 830 and the edge ring 820 may include a tapered notch and protrusion architecture similar to the alignment feature between the edge ring 820 and the shadow ring 835.

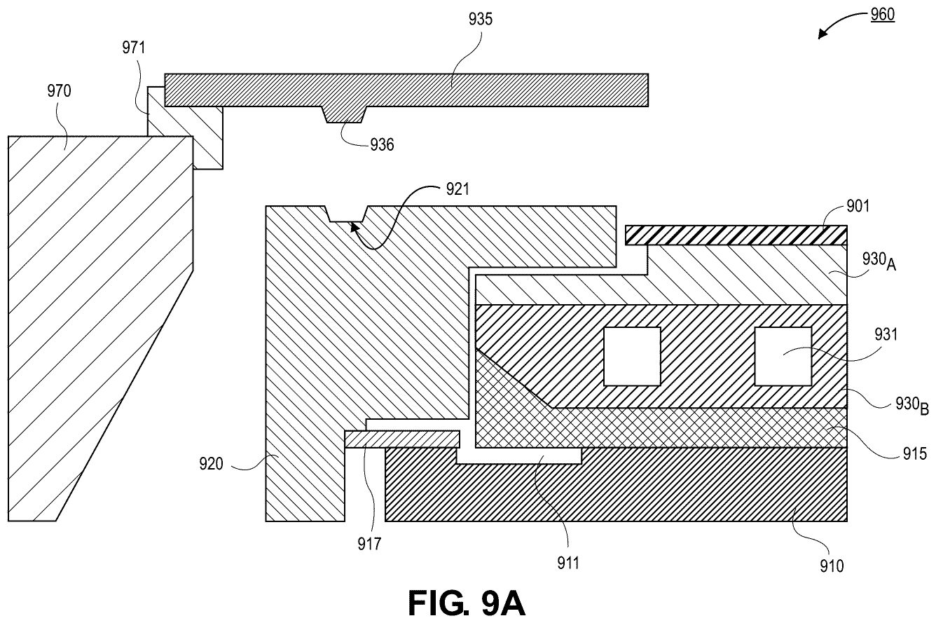

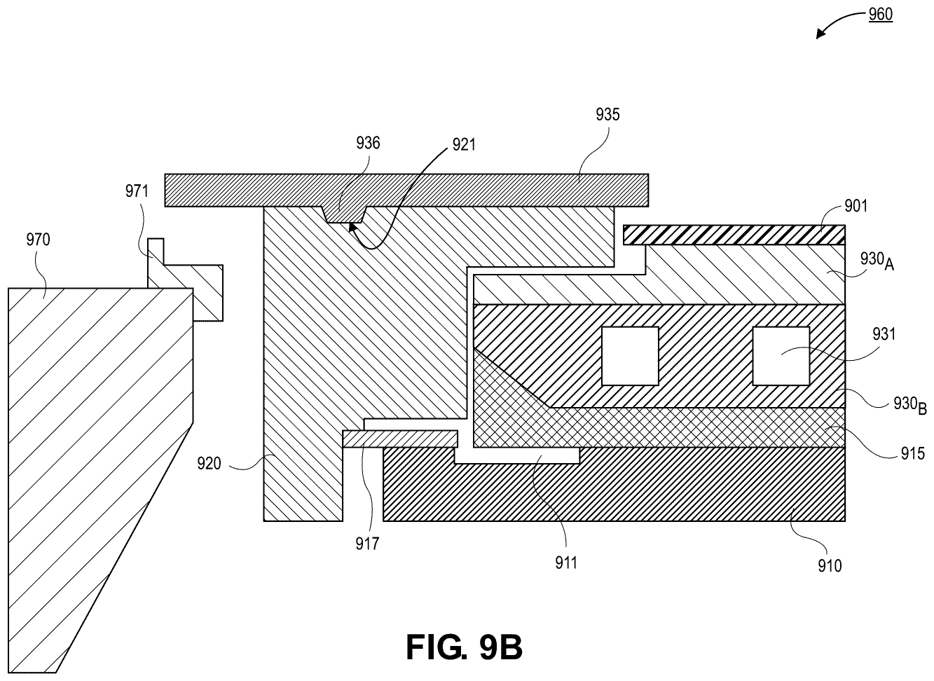

Referring now to FIGS. 9A and 9B, a pair of cross-sectional illustrations depicting portions of a processing tool with the pedestal at different locations (in the Z-direction) are shown, in accordance with an embodiment. In FIG. 9A, the pedestal is at a lower position within the chamber. The position of the pedestal in FIG. 9A is where the wafer is inserted or removed from the chamber through a slit valve. In FIG. 9B, the pedestal is at a raised position within the chamber. The position of the pedestal in FIG. 9B is where the wafer is processed.

Referring now to FIG. 9A, a cross-sectional illustration of a displaceable column 960 in a first position is shown, in accordance with an embodiment. As shown in FIG. 9A, the column includes a baseplate 910, an insulating layer 915, a pedestal 930 (i.e., first portion 930A and second portion 930B), and an edge ring 920. Such components may be substantially similar to the similarly named components described above. For example, cooling channels 931 may be provided in the second portion 930B of the pedestal 930, a channel 911 may be disposed in the baseplate 910, and a seal 917 may be provided between the edge ring 920 and the baseplate 910.

As shown in FIG. 9A, a wafer 901 is placed over a top surface of the pedestal 930. The wafer 901 may be inserted into the chamber through a slit valve (not shown). Additionally, the shadow ring 935 is shown at a raised position above the edge ring 920. Since the inner diameter of the shadow ring 935 is smaller than the diameter of the wafer 901, the wafer 901 needs to be placed on the pedestal before the shadow ring 935 is brought into contact with the edge ring 920.

In an embodiment, the shadow ring 935 is supported by a chamber liner 970. The chamber liner 970 may surround an outer perimeter of the column 960. In an embodiment, a holder 971 is positioned on a top surface of the chamber liner 970. The holder 971 is configured to hold the shadow ring 935 at an elevated position above the edge ring 920 when the column 960 is in the first position. In an embodiment, the shadow ring 935 includes a protrusion 936 for aligning with a notch 921 in the edge ring 920.

Referring now to FIG. 9B, a cross-sectional illustration of the column 960 after the shadow ring 935 is engaged is shown, in accordance with an embodiment. As shown, the column 960 is displaced in the vertical direction (i.e., the Z-direction) until the shadow ring 935 engages the edge ring 920. Additional vertical displacement of the column 960 lifts the shadow ring 935 off of the holder 971 on the chamber liner 970. In an embodiment, the shadow ring 935 is aligned properly as a result of the alignment features in the shadow ring 935 and the edge ring 920 (i.e., the notch 921 and the protrusion 936). In an additional embodiment, an alignment feature (not shown) may also be provided between the pedestal 930 and the edge ring 920. The alignment feature between the pedestal 930 and the edge ring 920 may include a tapered notch and protrusion architecture similar to the alignment feature between the edge ring 920 and the shadow ring 935.

While in the second position, the wafer 901 may be processed. Particularly, the processing may include formation of a positive or negative tone metal-oxide photoresist material over a top surface of the wafer 901. For example, the process may include a post development treatment process such as described above. In a particular embodiment, the positive or negative tone photoresist is a metal-oxo positive or negative tone photoresist suitable for EUV patterning. However, it is to be appreciated that the positive or negative tone photoresist may be any type of positive or negative tone photoresist, and the patterning may include any lithography regime. During deposition of the positive or negative tone metal-oxide photoresist onto the wafer 901, an inert gas may be flown along the fluidic channel between the interior surface of the edge ring 910 and the outer surfaces of the insulating layer 915, the pedestal 930, and the wafer 901. As such, positive or negative tone metal-oxide photoresist deposition along the edge or backside of the wafer 901 is substantially eliminated. In an embodiment, the wafer temperature 901 may be maintained between approximately −40° C. and approximately 200° C. by the cooling channels 931 in the second portion of the pedestal 930B.

Referring now to FIG. 10A, a sectional illustration of a processing tool 1000 is shown, in accordance with an additional embodiment. As shown in FIG. 10A, the column includes a baseplate 1010. The baseplate 1010 may be supported by a pillar 1014 that extends out of the chamber. That is, in some embodiments, the baseplate 1010 and the pillar 1014 may be discrete components instead of a single monolithic part as shown in FIG. 7. The pillar 1014 may have a central channel for routing electrical connections and fluids (e.g., cooling fluids and inert gasses for the purge flow).

In an embodiment, an insulating layer 1015 is disposed over the baseplate 1010, and a pedestal 1030 (i.e., first portion 1030A and second portion 1030B) are disposed over the insulating layer 1015. In an embodiment, coolant channels 1031 are provided in the second portion 1030B of the pedestal 1030. A wafer 1001 is disposed over the pedestal 1030.

In an embodiment, an edge ring 1020 is provided around the baseplate 1010, the insulating layer 1015, the pedestal 1030, and the wafer 1001. The edge ring 1020 may be coupled to the baseplate 1013 by a fastening mechanism 1013, such as a bolt, pin, screw, or the like. In an embodiment, a seal 1017 blocks the purge gas from exiting the column out the bottom between a gap between the baseplate 1010 and the edge ring 1020.

In the illustrated embodiment, the pedestal 1030 is in the first position. As such, the shadow ring 1035 is supported by the holders 1071 and the chamber liner 1070. As the pedestal 1030 is displaced vertically, the edge ring 1020 will engage with the shadow ring 1035 and lift the shadow ring 1035 off of the holders 1071.

Referring now to FIG. 10B, a sectional illustration of the chamber 1000 is shown, in accordance with an additional embodiment. In the illustration of FIG. 10B, the insulating layer 1015 and the pedestal 1030 are omitted in order to more clearly see the construction of the baseplate 1010. As shown, the baseplate 1010 may include a plurality of channels 1011 that provide fluidic routing from a center of the baseplate 1010 to an edge of the baseplate 1010. In the illustrated embodiment, a plurality of first channels connect the center of the baseplate 1010 to a first ring channel, and a plurality of second channels connect the first ring channel to the outer edge of the baseplate 1010. In an embodiment, the first channels and the second channels are misaligned from each other. While a specific configuration of channels 1011 is shown in FIG. 10B, it is to be appreciated that any channel configuration may be used to route inert gasses from the center of the baseplate 1010 to the edge of the baseplate 1010.

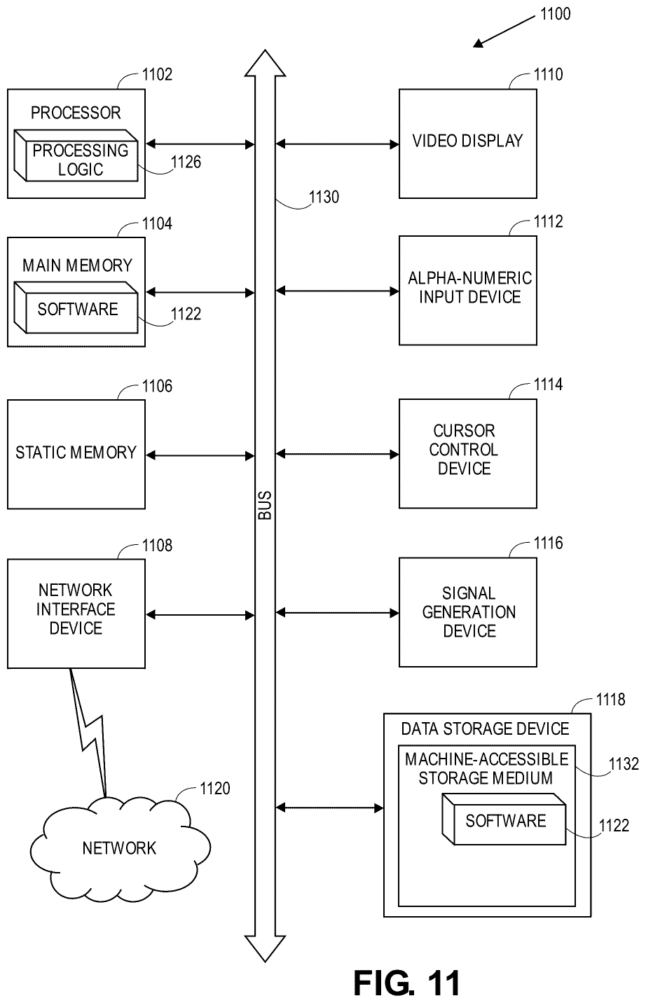

FIG. 11 illustrates a diagrammatic representation of a machine in the exemplary form of a computer system 1100 within which a set of instructions, for causing the machine to perform any one or more of the methodologies described herein, may be executed. In alternative embodiments, the machine may be connected (e.g., networked) to other machines in a Local Area Network (LAN), an intranet, an extranet, or the Internet. The machine may operate in the capacity of a server or a client machine in a client-server network environment, or as a peer machine in a peer-to-peer (or distributed) network environment. The machine may be a personal computer (PC), a tablet PC, a set-top box (STB), a Personal Digital Assistant (PDA), a cellular telephone, a web appliance, a server, a network router, switch or bridge, or any machine capable of executing a set of instructions (sequential or otherwise) that specify actions to be taken by that machine. Further, while only a single machine is illustrated, the term “machine” shall also be taken to include any collection of machines (e.g., computers) that individually or jointly execute a set (or multiple sets) of instructions to perform any one or more of the methodologies described herein.

The exemplary computer system 1100 includes a processor 1102, a main memory 1104 (e.g., read-only memory (ROM), flash memory, dynamic random access memory (DRAM) such as synchronous DRAM (SDRAM) or Rambus DRAM (RDRAM), etc.), a static memory 1106 (e.g., flash memory, static random access memory (SRAM), MRAM, etc.), and a secondary memory 1118 (e.g., a data storage device), which communicate with each other via a bus 1130.

Processor 1102 represents one or more general-purpose processing devices such as a microprocessor, central processing unit, or the like. More particularly, the processor 1102 may be a complex instruction set computing (CISC) microprocessor, reduced instruction set computing (RISC) microprocessor, very long instruction word (VLIW) microprocessor, processor implementing other instruction sets, or processors implementing a combination of instruction sets. Processor 1102 may also be one or more special-purpose processing devices such as an application specific integrated circuit (ASIC), a field programmable gate array (FPGA), a digital signal processor (DSP), network processor, or the like. Processor 1102 is configured to execute the processing logic 1126 for performing the operations described herein.

The computer system 1100 may further include a network interface device 1108. The computer system 1100 also may include a video display unit 1110 (e.g., a liquid crystal display (LCD), a light emitting diode display (LED), or a cathode ray tube (CRT)), an alphanumeric input device 1112 (e.g., a keyboard), a cursor control device 1114 (e.g., a mouse), and a signal generation device 1116 (e.g., a speaker).

The secondary memory 1118 may include a machine-accessible storage medium (or more specifically a computer-readable storage medium) 1132 on which is stored one or more sets of instructions (e.g., software 1122) embodying any one or more of the methodologies or functions described herein. The software 1122 may also reside, completely or at least partially, within the main memory 1104 and/or within the processor 1102 during execution thereof by the computer system 1100, the main memory 1104 and the processor 1102 also constituting machine-readable storage media. The software 1122 may further be transmitted or received over a network 1120 via the network interface device 1108.

While the machine-accessible storage medium 1132 is shown in an exemplary embodiment to be a single medium, the term “machine-readable storage medium” should be taken to include a single medium or multiple media (e.g., a centralized or distributed database, and/or associated caches and servers) that store the one or more sets of instructions. The term “machine-readable storage medium” shall also be taken to include any medium that is capable of storing or encoding a set of instructions for execution by the machine and that cause the machine to perform any one or more of the methodologies of the present disclosure. The term “machine-readable storage medium” shall accordingly be taken to include, but not be limited to, solid-state memories, and optical and magnetic media.

In accordance with an embodiment of the present disclosure, a machine-accessible storage medium has instructions stored thereon which cause a data processing system to perform a method of dry developing a positive or negative tone metal-oxide photoresist layer.

Thus, methods for post development treatment of a positive tone or negative tone photoresist have been disclosed.

What is claimed is:

1. A method, comprising:
depositing a metal-oxide photoresist over a substrate;
exposing the metal-oxide photoresist with an extreme ultra-violet (EUV) exposure to form exposed regions and unexposed regions;
developing the exposed metal-oxide photoresist; and
performing a surface treatment of the developed metal-oxide photoresist to form a coating on the developed metal-oxide photoresist.

2. The method of claim 1, wherein performing the surface treatment of the developed metal-oxide photoresist is performed at the same time and in a same processing chamber as performing an ultra-violet (UV) exposure of the developed metal-oxide photoresist.

3. The method of claim 1, wherein the surface treatment is performed at a temperature in the range of 20-500 degrees Celsius, at a pressure in the range of 10 mTorr to 500 Torr, using a chemical flow in the range of 100 mg/min to 5000 mg/min, and using an inert carrier gas of Ar, N₂ or He.

4. The method of claim 1, wherein the surface treatment is performed using a precursor selected from the group consisting of the following precursors:

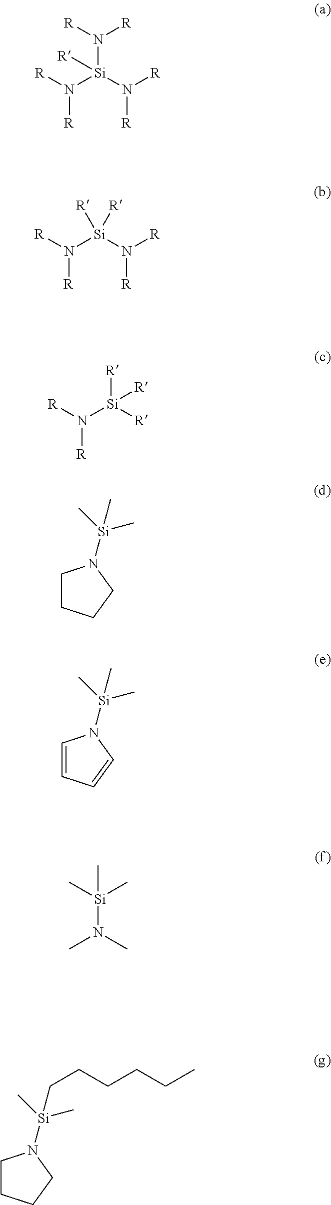

5. The method of claim 1, wherein the surface treatment is performed using a precursor selected from the group consisting of the following precursors:

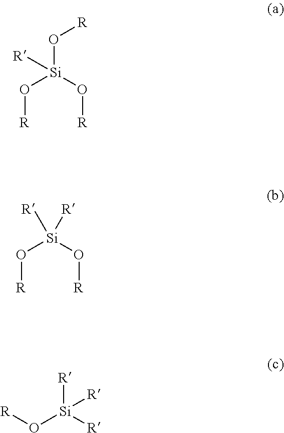

6. The method of claim 1, wherein the surface treatment is performed using a precursor selected from the group consisting of the following precursors:

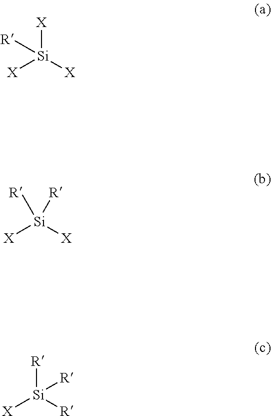

7. The method of claim 1, wherein the surface treatment is performed using the following precursor:

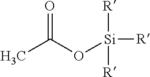

8. The method of claim 1, further comprising:
using the coated developed metal-oxide photoresist as a mask to etch the substrate or an under layer between the substrate and the coated developed metal-oxide photoresist.

9. The method of claim 1, wherein the metal-oxide photoresist is deposited using spin on or dry deposition.

10. The method of claim 1, wherein a thermal bake, a plasma treatment, or a UV treatment is performed after depositing the metal-oxide photoresist and prior to exposing the metal-oxide photoresist with the extreme ultra-violet (EUV) exposure.

11. A method, comprising:
depositing a metal-oxide photoresist over a substrate;
exposing the metal-oxide photoresist with an extreme ultra-violet (EUV) exposure to form exposed regions and unexposed regions;
developing the exposed metal-oxide photoresist;
performing a surface treatment of the developed metal-oxide photoresist to form a coating on the developed metal-oxide photoresist; and
exposing the coated developed metal-oxide photoresist with an ultra-violet (UV) exposure.

12. The method of claim 11, wherein performing the surface treatment and exposing the coated developed metal-oxide photoresist is performed in a same chamber at substantially the same time.

13. The method of claim 11, wherein the ultra-violet (UV) exposure is performed with a UV wavelength in the range of 150-500 nm.

14. The method of claim 11, wherein the surface treatment is performed at a temperature in the range of 20-500 degrees Celsius, at a pressure in the range of 10 mTorr to 500 Torr, using a chemical flow in the range of 100 mg/min to 5000 mg/min, and using an inert carrier gas of Ar, N₂ or He.

15. The method of claim 11, wherein the surface treatment is performed using a precursor selected from the group consisting of the following precursors:

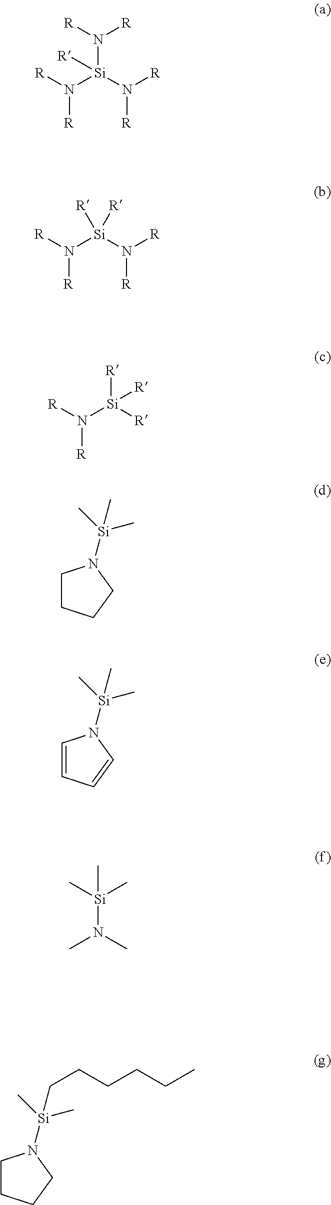

16. The method of claim 11, wherein the surface treatment is performed using a precursor selected from the group consisting of the following precursors:

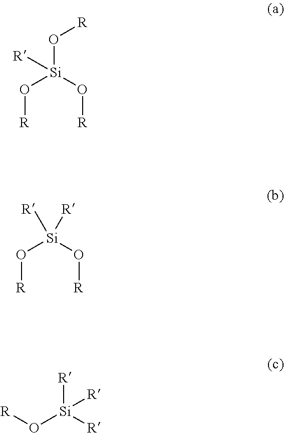

17. The method of claim 11, wherein the surface treatment is performed using a precursor selected from the group consisting of the following precursors:

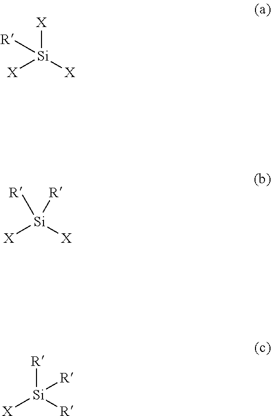

18. The method of claim 11, wherein the surface treatment is performed using the following precursor:

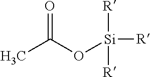

19. A system, comprising:
a chamber for receiving a developed metal-oxide photoresist thereon, performing a surface treatment of the developed metal-oxide photoresist to form a coating on the developed metal-oxide photoresist, and performing an ultra-violet (UV) exposure of the developed metal-oxide photoresist.

20. The system of claim 19, wherein performing the surface treatment of the developed metal-oxide photoresist is performed at the same time as performing the ultra-violet (UV) exposure of the developed metal-oxide photoresist, wherein the chamber is configured to perform the surface treatment at a temperature in the range of 20-500 degrees Celsius, at a pressure in the range of 10 mTorr to 500 Torr, using a chemical flow in the range of 100 mg/min to 5000 mg/min. and using an inert carrier gas of Ar, N₂ or He, and wherein the chamber is configured to perform the ultra-violet (UV) exposure is with a UV wavelength in the range of 150-500 nm.
